(19) United States
(12) Patent Application Publication
(10) Pub. No.: US 2009/0067130 A1
(43) Pub. Date: Mar. 12, 2009

(54) Arrangement for heat dissipation

(75) Inventors: Heiko Hahn, Ingolstadt (DE); Bernhard Heigl, Nassenfels (DE); Thomas Rossler, Hofstetten (DE); Richard Wauschek, Manching (DE); Thomas Michael, Lenting (DE)

Correspondence Address: CONTINENTAL TEVES, INC., ONE CONTINENTAL DRIVE, AUBURN HILLLS, MI, 48326-1581, US

(73) Assignee: CONTI TEMIC MICROELECTRONIC GMBH

(21) Appl. No.: 11/887,024

(22) PCT Filed: Feb. 18, 2006
(86) PCT No.: PCT/DE2006/000302

§ 371 Date: Sep. 24, 2007

(30) Foreign Application Priority Data
Mar. 24, 2005 (DE) 10 2005 014 413.6

(51) Int. Cl. H05K 7/20

(52) U.S. Cl. 361/707

(57) ABSTRACT

The invention relates to an arrangement for heat dissipation. The arrangement comprises a printed circuit board and at least one electrical and/or electronic component, with a power supply unit supplying electrical power to the electrical and/or electronic component (21). The power supply unit and the electrical and/or electronic component make electrical contact, and are thermally coupled. The power supply unit is also used for dissipation of thermal power losses from the electrical and/or electronic component.

### BACKGROUND OF THE INVENTION

The invention relates to an arrangement for heat dissipation consisting of a printed circuit board (22) and at least one electrical and/or electronic component (21) arranged thereon, wherein a current supply unit (23) supplies the electrical and/or electronic component (21) with electrical power, for which purpose the current supply unit (23) electrically contacts the electrical and/or electronic component.

Frequently, printed circuit boards are equipped with electrical and/or electronic components, which produce a high waste heat, which, in turn, must be kept off from and dissipated from the component, from the printed circuit board and from adjacent components, in order not to damage the component itself, the printed circuit board or the adjacent components.

Thus, for example from DE-OS-27 43 647 it is known to mount such components with high waste heat onto a metal plate, which is covered for electric insulation with an electrically insulating foil. The components are mounted onto the metal plate, however, with the insulating foil of the heat dissipation setting against a thermal resistance.

From DE-A-38 29 117 a further printed circuit board is known, which comprises a metal core, which is coated by a dielectric material. The metal core is formed such that the lost heat from building components can be directly dissipated via it. In addition, a defined position of the metal core can be produced during injection moulding and thus a perfect connection of the coating with the metal core can be ensured.

From DE-A-43 26 506 an electrical device with a conductor foil carrying the electronic circuit is known, which is equipped with SMD power components. For mechanical stabilization and for heat dissipation of the waste heat produced by the power components the conductor foil is applied on a mounting plate. Underneath the power component a solderable edge layer is embodied on the conductor foil, which limits a large surface recess. This recess is filled up with a heat conducting mass, so that a large surface heat transport from the power component to the mounting plate is possible.

From DE-A-195 32 992 a on one-sided equipped printed circuit board is known, on which back side under insertion of an intermediate layer a cooling plate is applied. The printed circuit board carries at least one thermally highly stressable component. The bearing surface of this component is connected to the cooling plate by a heat conducting bridge in form of a metal body or a copper bolt. The metal body is located in a recess, which connects the bearing surface of the component to the cooling plate right through the intermediate layer.

From DE-A-196 01 649 a further arrangement for improving the heat dissipation with electrical and electronic components is known, in which a printed circuit board carrying the components is substance-to-substance connected to a metal plate via an insulation layer. In the vicinity of at least one component corresponding openings are inserted into the printed circuit board and into the insulation layer. The metal plate comprises elevations, the height of which corresponds approximately to the thickness of the printed circuit board and of the insulation layer or exceeds this also slightly. The elevations are passed through the openings.

Finally, from DE-A-198 05 492 a printed circuit board is known, which is equipped with at least one heat conveying electronic component. Further, it is provided with a metallic plate serving for heat dissipation. A heat conducting connecting element protrudes between the component and the metallic plate from a copper layer which is covered on both sides with an insulating foil. The connecting element is etched as an integral part out of the copper layer.

With all arrangements, devices and printed circuit boards known from prior art it is disadvantageous that a supply of the energy is always made separately via copper conductor paths, however, at the same time it must always separately be taken into consideration that a sufficient dissipation and removal of the heat power loss of the electrical and/or electronic components on the printed circuit board is ensured. This requires mostly a larger dimensioning of distance spaces between the components and the use of cooling bodies, what, in turn, opposes the potential savings of printed circuit board surface.

It is, therefore, the object of the invention to ensure an effective dissipation of heat power loss of components and at the same time to allow for a saving of printed circuit board surface.

### SUMMARY OF THE INVENTION

This object is achieved by an arrangement for heat dissipation, consisting of a printed circuit board (22) and at least one electrical component (21) arranged thereon, wherein a current supply unit (23) supplies the electrical component (21) with electrical power, for which purpose the current supply unit (23) electrically contacts the electrical component. The electrical component (21) and the current supply unit (23) are thermally coupled and the current supply unit (23) serves for dissipation of thermal power losses from the electrical and/or electronic component (21). Advantageous embodiments of the invention become apparent on the basis of the further description and the figures.

### BRIEF DESCRIPTION OF THE DRAWINGS

The invention will be described in the following on the basis of figures, which show:

FIG. 1 an arrangement of prior art on a printed circuit board in a schematic sectional view perpendicular to the surface of the printed circuit board;

FIG. 2 a first arrangement according to invention on a printed circuit board in a schematic sectional view perpendicular to the surface of the printed circuit board;

FIG. 3 a second arrangement according to invention on a printed circuit board in a schematic sectional view perpendicular to the surface of the printed circuit board;

FIG. 4 a third arrangement according to invention on a printed circuit board in a schematic sectional view perpendicular to the surface of the printed circuit board;

FIG. 5 a fourth arrangement according to invention on a printed circuit board in a schematic sectional view perpendicular to the surface of the printed circuit board;

FIG. 6 a fifth arrangement according to invention in exploded representation in an inclined top view onto the printed circuit board.

### DETAILED DESCRIPTION OF THE DRAWINGS

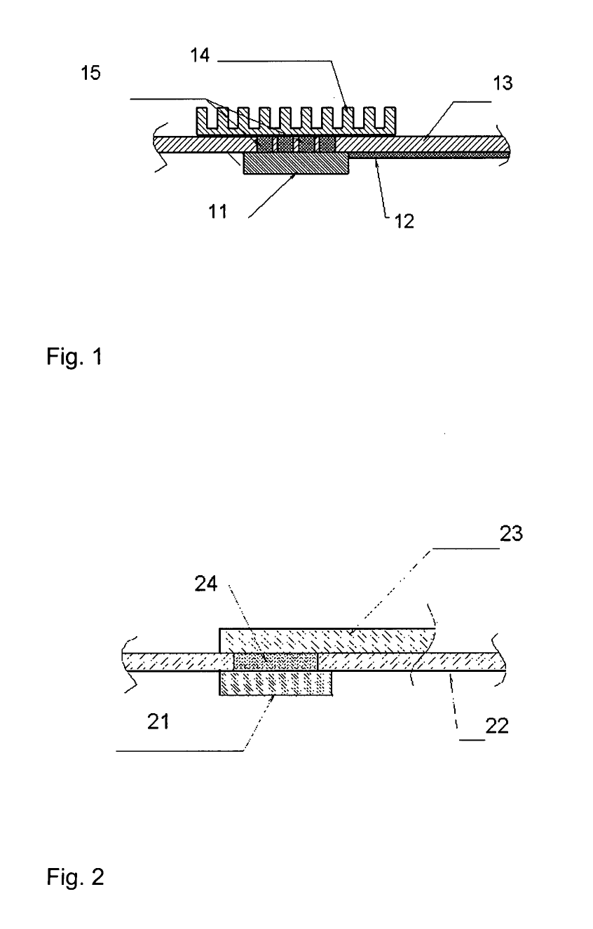

FIG. 1 shows an arrangement, which corresponds to the state of the art. This arrangement shows a printed circuit board 13, on which an electrical component 11 is arranged, which is mostly solder-technically connected to conductor paths 12, which again are arranged on the printed circuit board 13. The conductor paths are fixed in known manner on the printed circuit board 13. In the operational stage, the electrical component 11 produces a thermal power loss, which must be guided by the electrical component 11 and by the printed circuit board 13, in order to avoid a damage due to overheating. For this purpose, as shown in exemplary mode in FIG. 1, the electrical component 11 is connected to a cooling body 14. The connection is made via a material for thermal coupling 15. Via the cooling body 14 the thermal power loss of the electrical component 11 is derived via convection or radiation to the environment.

In the following the reference numerals for substantial elements of the invention used for describing the invention are maintained in FIG. 2 to 5 for equivalent components for reasons of clarity. In the description of the invention only those elements which are substantial for the invention are described.

In FIG. 2 a first arrangement according to invention is described. FIG. 2 shows a printed circuit board 22, an electrical/electronic component 21, a material 24 for the thermal and electrical coupling and a current supply unit 23. Naturally, the printed circuit board 22 comprises conductor paths, or rather the printed circuit board 22 can comprise conductor paths, which will be arranged or are arranged on it in usual and known manner.

The electrical/electronic component 21 is arranged on the printed circuit board 22 and is fixed by means of known technology, e.g. soldering or adhesive method or also in SMD technology, on the printed circuit board 22 and is connected to the conductor paths of the printed circuit board 22. The electrical/electronic component 21 is supplied with current, i.e. with electrical power, via the current supply unit 23. In FIG. 2 the electrical/electronic component 21 and the current supply unit 23 are arranged on different sides each of the printed circuit board 22. For thermal and electrical coupling the current supply unit 23 is connected via the material 24 to the electrical/electronic component 21 via break throughs or holes especially provided in the printed circuit board of 22. This material 24 for thermal and electrical coupling is optimized with regard to thermal and electrical conductivity and ensures an optimal thermal coupling and dissipation of waste heat and thermal power loss, respectively, of the electrical/electronic component 21 to the current supply unit 23 and simultaneously, with a lowest possible Ohm's resistance with the conduction and supply of the electric current from the current supply unit 23 to the electrical/electronic component 21.

The waste heat, which is produced by the electrical/electronic component 21 and which must be dissipated, is led to the current supply unit 23. The latter derives the waste heat from the electrical/electronic component 21 and from the printed circuit board 22 and releases it e.g. in the form of radiation or convection to the environment.

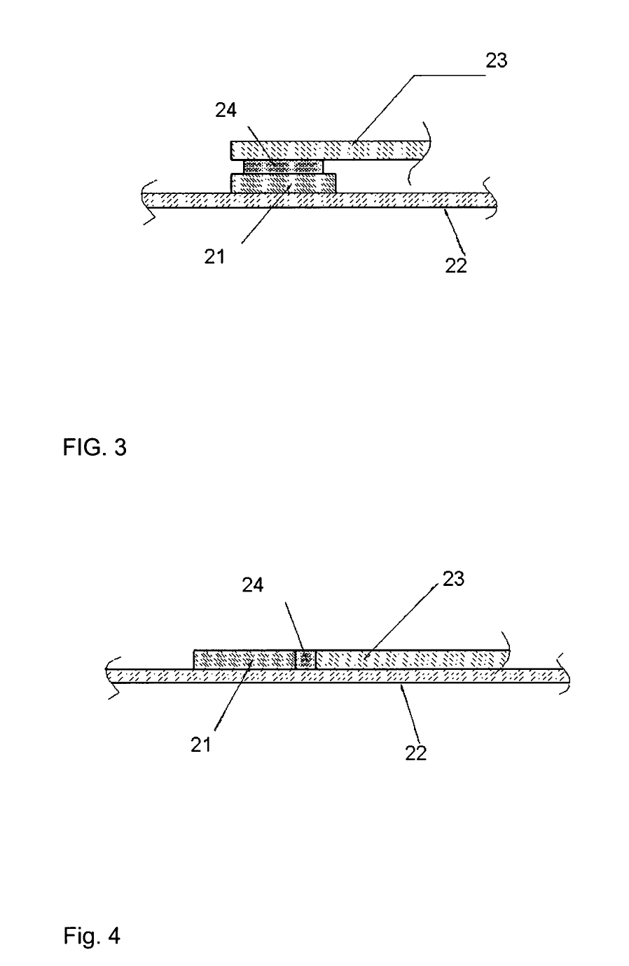

In FIG. 3 a second arrangement according to invention on a printed circuit board 22 is represented in a schematic sectional view perpendicular to the surface of the printed circuit board 22. Different to the arrangement in FIG. 2 the electrical/electronic component 21 with the current supply unit 23 is arranged on the same side of the printed circuit board 22. Also in this case a thermal and electrical connection between the current supply unit 23 and the electrical/electronic component 21 is made via the material 24 for thermal and electrical coupling. The current supply unit 23 serves also here both the supply of the electrical power necessary for the electrical/electronic component 21, and for the dissipation and removal of the waste heat produced by the electrical/electronic component 21.

However, in this form of embodiment it is advantageous that the current supply unit 23 is arranged over the electrical/electronic component 21 and that by means of suitable dimensioning and selection of the contacting of the current supply unit 23 and of the electrical/electronic component 21 a casing of the electrical/electronic component 21 via the current supply unit 23 can be effected and thus an effective avoidance of the radiation of electromagnetic fields of the electrical/electronic component 21 and an impact, respectively, of external electromagnetic fields onto the electrical/electronic component 21 is avoided.

In FIG. 4 a third arrangement according to invention on a printed circuit board 22 is represented in a schematic sectional view perpendicular to the surface of the printed circuit board 22. Different to the arrangement in FIGS. 2 and 3 the electrical/electronic component 21 is laterally electrically and thermally connected or rather contacted with the current supply unit 23.

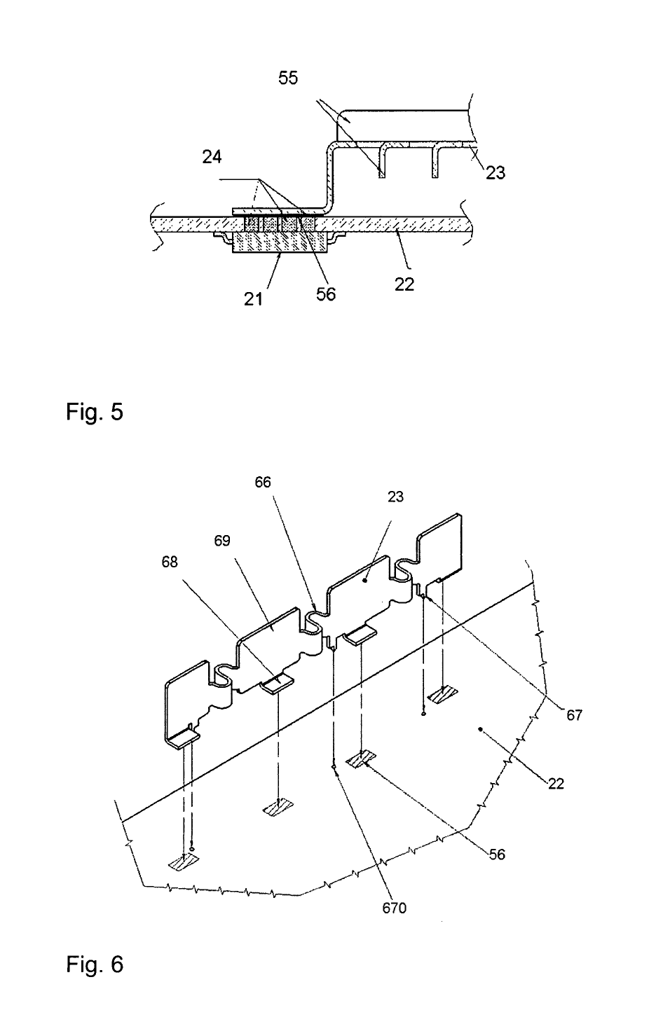

In FIG. 5 a fourth arrangement according to invention on a printed circuit board 22 is represented in a schematic sectional view perpendicular to the surface of the printed circuit board 22. In principle, this is comparable to the arrangement in FIG. 2, however, it has further advantages. By the shaping of the current supply unit 23 the latter can derive particularly effectively the waste heat of the electrical/electronic component 21. In addition, the current supply unit 23 comprises cooling fins 55, which increase in particular the surface for radiation and release of the absorbed waste heat and thus serve for a better dissipation of the waste heat. Furthermore, the electrical/thermal connection 56 between the electrical/electronic component 21 and the current supply unit 23 is evident, which preferably is implemented in SMD soldering technology.

In FIG. 6 a fifth arrangement according to invention is shown in exploded representation in an inclined top view on the printed circuit board 22. It shows on the printed circuit board 22 the places for the electrical-thermal connection 56 of the current supply unit 23, which, in turn, comprises contact elements 68, which realize this connection on the side of the current supply unit 23. Furthermore, fixing bores 670 are provided on the printed circuit board 22, into which locating pins 67 of the current supply unit 23 are to be inserted, in order to fix the current supply unit 23 perfectly fitting on the printed circuit board and to ensure a stable hold of the current supply unit 23 on the printed circuit board grant. In particular, when heating the current supply unit 23 the locating pins 67 inserted into the printed circuit board 22 ensure that the position of the current supply unit 23 on the printed circuit board 22 does not change, despite mechanical expansion of the current supply unit 23 in consequence of the heating. The current supply unit 23 comprises dissipation regions 69, which correspond from their function to the cooling fins 55 from FIG. 5. These dissipation regions 69 serve for removing the heat power loss of the electrical/electronic component 21. Finally, the current supply unit 23 comprises also meanders 66. They serve for compensating the thermal expansion of the current supply unit 23. By these meanders 66 it is ensured that during heating and material expansion in this regard of the current supply unit 23 the arising forces are absorbed by the mechanical deformation of the meanders 66 and an increased force effect on the printed circuit board 22 by thermal tension is avoided.

In a further advantageous embodiment of the invention the current supply unit 23 is provided with a blackened surface, whereby the heat dissipation is improved by radiation.

In an advantageous manner the current supply unit 23 is embodied as a bus bar.

### LIST OF REFERENCE NUMERALS

11 electrical component
12 conductor path(s)
13 printed circuit board
14 cooling body
15 material for thermal coupling
21 electrical and/or electronic component
22 printed circuit board
23 current supply unit
24 material for electrical and thermal coupling
55 cooling fins
56 electrical/thermal connection
66 meander
67 locating pin
68 contact element
69 dissipation region
670 fixing bore

1-10. (canceled)

11. An arrangement for heat dissipation, comprising:
a printed circuit board (22); and
at least one electrical component (21) arranged the circuit board, wherein a current supply unit (23) supplies the electrical component (21) with electrical power and the electronic component (21) and the current supply unit (23) are thermally coupled and the current supply unit (23) provides dissipation of thermal power losses from the electrical component (21).

12. The arrangement for heat dissipation of claim 11, wherein the current supply unit (23) consists of a material with high heat conductivity and low electrical resistance.

13. The arrangement for heat dissipation of claim 12, wherein the current supply unit (23) is connected to the printed circuit board (22) in so that the current supply unit (23) dissipates the thermal power loss transferred by the component by at leas ton of convection, radiation, or conduction and releases it to the environment.

14. The arrangement for heat dissipation of claim 11, wherein the current supply unit (23) thermally contacts the electrical component (21) on a surface which is as large as possible.

15. The arrangement for heat dissipation of claim 11, wherein the current supply unit (23) contacts the electrical component (21) laterally or from above and that the current supply unit and the electrical and/or electrical component (21) are arranged on the same side of the printed circuit board (22).

16. The arrangement for heat dissipation of claim 11, wherein the current supply unit (23) contacts the electrical component (21) via a break through or an opening of the printed circuit board (22) via the thermal coupling and the current supply unit (23) and the electrical component (21) are arranged on an opposite side of the printed circuit board (22).

17. The arrangement for heat dissipation of claim 11, wherein the current supply unit (23) comprises cooling fins (55).

18. The arrangement for heat dissipation of claim 17, wherein the cooling fins (55) are formed so that the natural heat flow is supported in the current supply unit (23).

19. The arrangement for heat dissipation of claim 11, wherein the current supply unit (23) comprises at least one meander (66).

20. The arrangement for heat dissipation of claim 11, wherein the current supply unit (23) is a bus bar.

21. The arrangement for heat dissipation of claim 11, wherein the electrical component is an electronic component.
